(19) United States
(12) Patent Application Publication
(10) Pub. No.: US 2016/0020367 A1
(43) Pub. Date: Jan. 21, 2016

(54) METHOD FOR FABRICATING PACKAGE STRUCTURE

(71) Applicant: ACHROLUX INC., Sunnyvale, CA (US)

(72) Inventors: Peiching Ling, Sunnyvale, CA (US); Dezhong Liu, Sunnyvale, CA (US)

(21) Appl. No.: 14/798,720

(22) Filed: Jul. 14, 2015

(30) Foreign Application Priority Data
Jul. 15, 2014 (TW) 103124227

(51) Int. Cl. H01L 33/54; H01L 33/44; H01L 33/50; H01L 33/62; H01L 33/00

(52) U.S. Cl. CPC H01L 33/54; H01L 33/62; H01L 33/0095; H01L 33/505; H01L 33/44; H01L 2933/0025; H01L 2933/005; H01L 2933/0041; H01L 2933/0066

(57) ABSTRACT

A method for fabricating a package structure is provided. At least one light emitting component is sucked and adhered to a carrier. An encapsulating member encapsulates the light emitting component. A conductive component is connected to the light emitting component.

### BACKGROUND OF THE INVENTION

1. Field of the Invention

This invention relates to methods for fabricating package structures, and, more particularly, to a method for fabricating a package structure that emits light.

2. Description of Related Art

With the rapid development of electronic industry, modern electronic products have low profile, compact size, and a variety of functions. Light emitting diodes (LEDs), as having many significant advantages, such as long lifespan, small volume, high shock resistance and low power consumption, have been widely applied to electronic produces that demand illumination.

FIGS. 1A and 1B are cross sectional views illustrating a method for fabricating an LED package 1 according to the prior art. A reflective cup 11 is formed on a substrate 10. The reflective cup 11 has an opening 110. An LED component is disposed in the opening 110. A plurality of conductive wires 120 such as gold wires electrically connect the LED component 12 with the substrate 10. An encapsulant 13 that has a phosphor powder layer encapsulates the LED component 12.

In the method for fabricating the LED package 1 according to the prior art, the conductive wires 120 electrically connect the LED component 12 with the substrate 10 before the formation of the encapsulant 13. Since the LED component 12 has no insulating material formed on a side surface thereof, the electrical connection of the conductive wires 120 to the LED component 12 and the substrate 10 has to be conducted by a wire bonding process. A conductive adhesive can be also used to electrically connect the LED component 12 with the substrate 10. However, the conductive adhesive is likely to overflow to the side surface of the LED component 12, and a front surface (P electrode) and the side surface (N electrode) of the LED component 12 are thus likely conducted and shorted.

Therefore, there is a limited number of types of conductive components can be used in the LED package 1, and how to overcome this problem is becoming one of the critical issues in the art.

### SUMMARY OF THE INVENTION

In view of the above-mentioned problems of the prior art, the present invention provides a package structure, comprising: at least one light emitting component having an inactive side, a light emitting side opposing the inactive side, and a side surface adjacent to the inactive side and the light emitting side; an encapsulating member encapsulating the side surface of the light emitting component directly and defining a first surface and a second surface opposing the first surface, with the light emitting side of the light emitting component exposed from the first surface of the encapsulating member; a plurality of conductive parts disposed onto the encapsulating member, with the encapsulating member disposed between the side surface of the light emitting component and the conductive parts; and at least one conductive component disposed on the first surface of the encapsulating member and connected to the light emitting side of the light emitting component and the conductive parts.

The present invention further provides a method for fabricating a package structure, comprising: providing a plurality of conductive parts and at least one light emitting component that has an inactive side, a light emitting side opposing the inactive side, and a side surface adjacent to the inactive side and the light emitting side; encapsulating the light emitting component and the conductive parts with an encapsulating member, the encapsulating member encapsulating the side surface of the light emitting component directly, with the encapsulating layer disposed between the side surface of the light emitting component and the conductive parts, the encapsulating member defining a first surface and a second surface opposing the first surface, with the light emitting side of the light emitting component and the conductive parts exposed from the first surface of the encapsulating member; and forming at least one conductive component on the first surface of the encapsulating member, and connecting the light emitting side of the light emitting component to the conductive parts with the conductive component.

The present invention yet provides a carrier, comprising: at least a placement part; and a plurality of conductive parts disposed at the same plane as the placement part and having a height greater than a height of the placement part.

According to the package structure and the method for fabricating the package structure according the present invention, the encapsulating member is used to encapsulate the side surface of the light emitting component, to isolate the side surface of the light emitting component from an external environment, and then the conductive component is formed. Therefore, the conductive component can be formed in a great number of ways, and the problem of the prior art that there is a limited number of types of conductive components is solved.

### BRIEF DESCRIPTION OF DRAWINGS

The invention can be more fully understood by reading the following detailed description of the preferred embodiments, with reference made to the accompanying drawings, wherein:

FIGS. 1A and 1B are cross sectional views illustrating a method for fabricating an LED package according to the prior art;

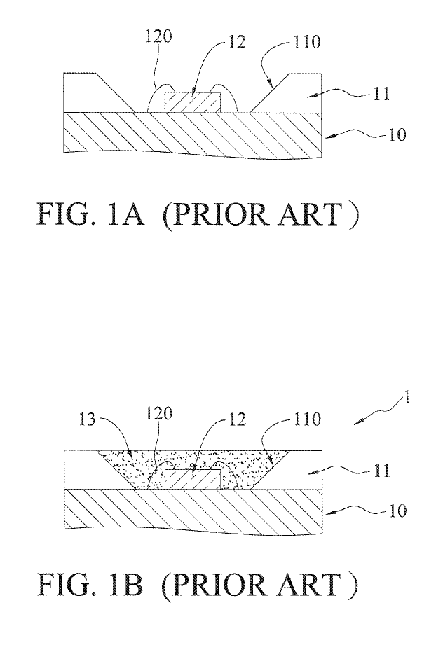

FIGS. 2A-2D′ are cross sectional views illustrating a method for fabricating a package structure of a first embodiment according to the present invention, wherein FIG. 2D illustrates another embodiment of FIG. 2D;

FIGS. 3A-3D are cross sectional views illustrating a method for fabricating a package structure of a second embodiment according to the present invention;

FIGS. 4A-4C are cross sectional views illustrating a method for fabricating a package structure of a third embodiment according to the present invention; and

FIGS. 5A-5C are cross sectional views illustrating a method for fabricating a package structure of a fourth embodiment according to the present invention.

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

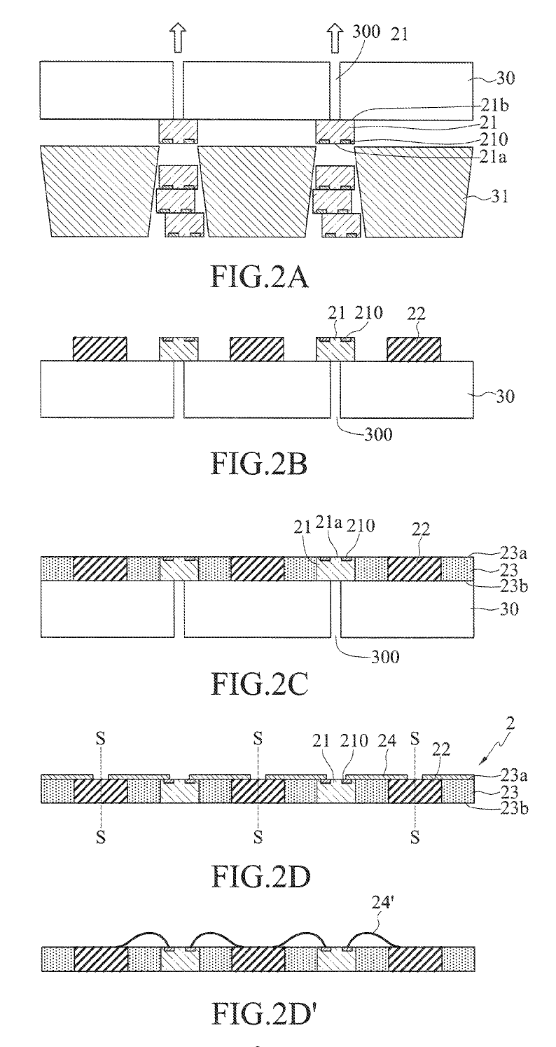

FIGS. 2A-2D′ are cross sectional views illustrating a method for fabricating a package structure 2 of a first embodiment according to the present invention.

As shown in FIG. 2A, vacuum equipment is used to suck and adhere a light emitting component 21 disposed in a receiving member 31 to a carrier 30.

In an embodiment, the carrier 30 has a plurality of sucking hole 300, and the light emitting component 21 is sucked and adhered to the sucking holes 300.

In an embodiment, the light emitting component 21 is a light emitting diode, and has an inactive side 21b coupled to the carrier 30, and a light emitting side 21a opposing the inactive side 21b, and the light emitting side 21a has a plurality of electrode pads 210 thereon.

In an embodiment, the inactive side 21 of the light emitting component 21 is used as a heat dissipating side of the light emitting component 21.

As shown in FIG. 2B, the carrier 30 is flipped over, and a plurality of conductive parts 22 are formed on the carrier 30 and disposed at the same side with the light emitting components 21.

As shown in FIG. 2C, an encapsulating member 23 is formed on the carrier 30 and encapsulates the light emitting component 21 and the conductive parts 22. The encapsulating member 23 defines a first surface 23a and a second surface 23b opposing the first surface 23a, and the light emitting side 21a of the light emitting component 21 and the conductive parts 22 are exposed from the first surface 23a of the encapsulating member 23.

In an embodiment, the encapsulating member 23 is silica gel such as white glue.

As shown in FIG. 2D, the vacuum state is released, and the carrier 30 is removed. Then, a plurality of conductive components 24 are formed on first surface 23a of the encapsulating member 23, and connect the conductive component 24 the electrode pads 210 of the light emitting component 21 and the conductive parts 22.

In an embodiment, the conductive component 24 is a conductive adhesive, such as silver glue or copper paste that are formed by a pasting method, or a patterned metal circuit that is formed by electroplating method. In another embodiment, a wire bonding process is selected, as shown in FIG. 2D′, in which the conductive component 24′ is a conductive wire.

Subsequently, a cutting process can be performed along a cutting path S.

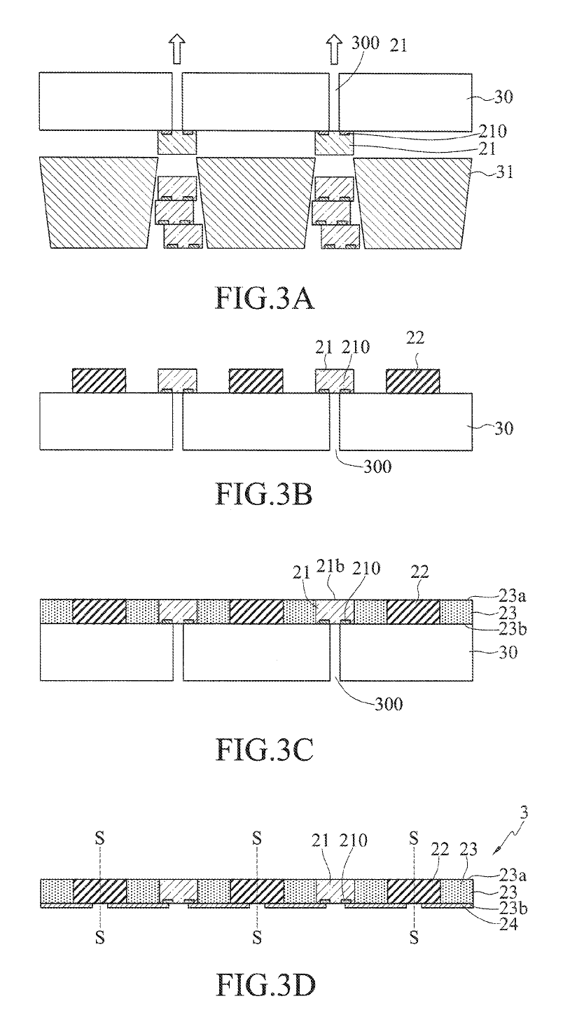

FIGS. 3A-3D are cross sectional views illustrating a method for fabricating a package structure of a second embodiment according to the present invention. The second embodiment differs from the first embodiment in the arrangement of the light emitting component.

As shown in FIG. 3A, vacuum equipment is used to suck and adhere a plurality of light emitting component 21 disposed in a receiving member 31 to a carrier 30.

In an embodiment, the sucking holes 300 of the carrier 30 are sucked and adhered to the light emitting side 21a of the light emitting component 21, and the light emitting side 21a of the light emitting component 21 is coupled to the carrier 30, with the light emitting side 21a of the light emitting component 21 facing toward the carrier 30.

As shown in FIG. 3B, the carrier 30 is flipped over, and a plurality of conductive parts 22 are formed on the carrier 30, with the conductive parts 22 disposed at the same side of the carrier 30 as the light emitting component 21.

As shown in FIG. 3C, an encapsulating member 23 is formed on the carrier 30, and encapsulates the light emitting component 21 and the conductive parts 22. The encapsulating member 23 defines a first surface 23a and a second surface 23b opposing the first surface 23a, and the inactive side 21b of the light emitting component 21 and the conductive parts 22 are exposed from the first surface 23a of the encapsulating member 23.

As shown in FIG. 3D, the vacuum state is released, and the carrier 30 is removed. Then, a plurality of conductive components 24 are formed on the second surface 23b of the encapsulating member 23, and coupled to the electrode pads 210 of the light emitting component 21 and the conductive parts 22, for the light emitting component 21 to dissipate heat.

Subsequently, a cutting process is performed along a cutting path S.

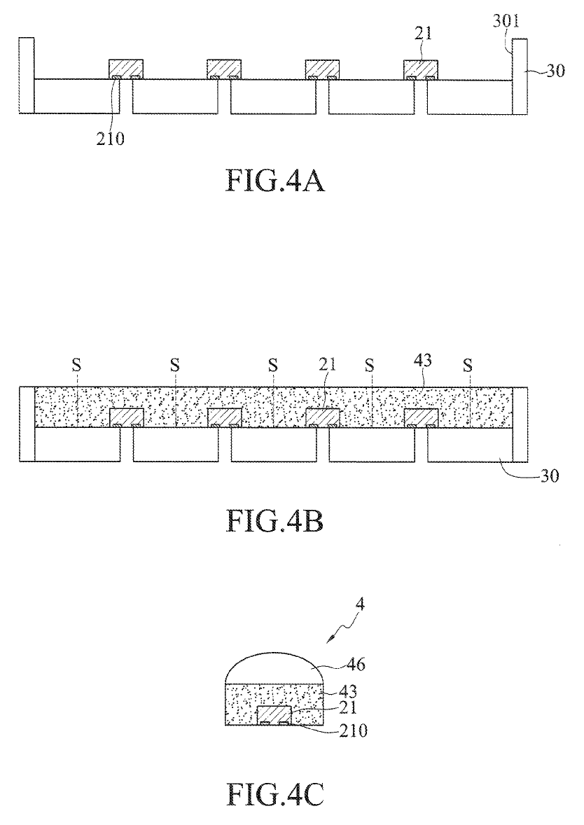

FIGS. 4A-4C are cross sectional views illustrating a method for fabricating a package structure of a third embodiment according to the present invention. The third embodiment differs from the first embodiment in the formation of the encapsulating member.

As shown in FIG. 4A, the carrier 30 has a groove 301, and the light emitting components 21 are sucked and adhered in the groove 301.

As shown in FIG. 4B, an encapsulating layer 43 having a plurality of phosphor particles is formed in the groove 301 and encapsulates the light emitting component 21s.

In an embodiment, the encapsulating layer 43 is formed by:

filling in the groove 301 a plurality of phosphor particles that encapsulate the light emitting component 21, and filling in the groove 301 liquid silica gel that seals the gaps of the phosphor particles;

mixing a plurality of phosphor particles with silica gel, and filling the mixture including the phosphor particles and the silica gel in the groove 301;

filing in the groove 301 a plurality of phosphor particles that encapsulate the light emitting components 21, forming on the particle particles an adhesive that fixes the phosphor particles, and filling liquid silica gel in the groove 301; or

providing a plurality of phosphor particles, each of which is covered by an adhesive material, filing in the groove 301 the phosphor particles covered by the adhesive material that encapsulate the light emitting components 21, and filling liquid silica gel in the groove 301.

As shown in FIG. 4C, a protection layer (not shown) that protects the encapsulating layer 43 or a light pervious layer 46 such as a lens is formed on the encapsulating layer 43, and a cutting process is performed along a cutting path S (as shown in FIG. 4B), to obtain a plurality of package structures 4 that emit light.

In an embodiment, after the cutting path S is performed, the vacuum state is released, and the carrier 30 is removed.

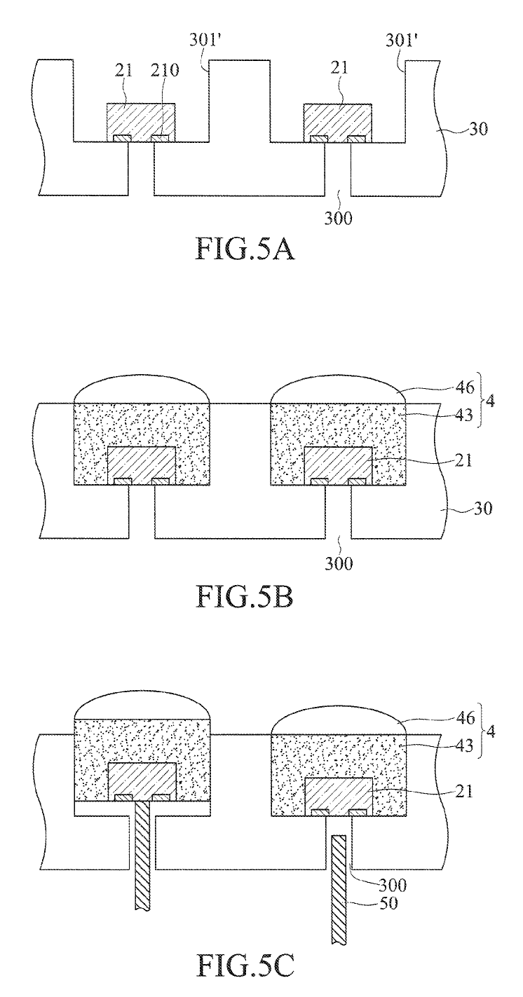

FIGS. 5A-5C are cross sectional views illustrating a method for fabricating a package structure of a fourth embodiment according to the present invention. The fourth embodiment differs from the third embodiment in the obtaining of the package structure.

As shown in FIG. 5A, the carrier 30 has a plurality of grooves 301′, and the light emitting components 21 are sucked and adhered to the corresponding grooves 301′. As shown in FIG. 5B, an encapsulating layer 43 is formed in the grooves 301′, and encapsulate the light emitting components 21. Then, a protection layer (not shown) that protects the encapsulating layer 43 or a light pervious layer 46 such as a lens is formed on the encapsulating layer 43, to obtain a plurality of package structures 4.

As shown in FIG. 5C, a pushing member 50 is used to be inserted into the sucking holes 300 of the carrier 30, and push the package structures 4 to move upward and leave the grooves 301′, so as to obtain the package structures 4.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method for fabricating a package structure, comprising:
sucking and adhering at least one light emitting component to a carrier;
forming a plurality of conductive parts on the carrier;
forming on the carrier an encapsulating member that encapsulates the light emitting component and the conductive parts, and has a first surface, from which the light emitting component and the conductive parts are exposed, and a second surface opposing the first surface; and
removing the carrier.

2. The method of claim 1, wherein the light emitting component is a light emitting diode.

3. The method of claim 1, when a plurality of the light emitting components are adhered to the carrier, further comprising performing a singulation process after the carrier is removed.

4. The method of claim 1, further comprising, after the carrier is removed, forming at least one conductive component on the first surface of the encapsulating member, and connecting the conductive component to the light emitting component and the conductive parts.

5. The method of claim 4, wherein the conductive component is a conductive adhesive, a conductive wire or a metal circuit.

6. The method of claim 1, further comprising, after the carrier is removed, forming at least one conductive component on the second surface of the encapsulating member, and connecting the conductive component to the light emitting component and the conductive parts.

7. The method of claim 6, wherein the conductive component is a conductive adhesive, a conductive wire or a metal circuit.

8. The method of claim 1, wherein the carrier has a groove, and the light emitting component is sucked in the groove.

9. The method of claim 3, wherein the carrier has a plurality of grooves, and the light emitting components are received in the grooves.

10. The method of claim 1, further comprising forming on the first surface of the encapsulating member a phosphor layer that covers a light emitting side of the light emitting component and the conductive component.

11. The method of claim 10, further comprising forming a protection layer or a light pervious layer on the phosphor layer.
